(19) United States
(12) Patent Application Publication
(10) Pub. No.: US 2012/0195444 A1
(43) Pub. Date: Aug. 2, 2012

(54) ELECTRONIC DEVICE AND METHOD OF DYNAMICALLY CORRECTING AUDIO OUTPUT OF AUDIO DEVICES

(75) Inventors: CHUNG-I LEE, Tu-Cheng (TW); CHIEN-FA YEH, Tu-Cheng (TW); DA-LONG LEE, Tu-Cheng (TW); TSUNG-HSIN YEN, Tu-Cheng (TW)

(73) Assignee: HON HAI PRECISION INDUSTRY CO., LTD., Tu-Cheng (TW)

(21) Appl. No.: 13/338,251

(22) Filed: Dec. 28, 2011

(30) Foreign Application Priority Data
Jan. 28, 2011 (TW) 100103203

(51) Int. Cl. H03G 3/20

(52) U.S. Cl. 381/107

(57) ABSTRACT

An electronic device and method of dynamically correcting audio output of audio devices creates a coordinate system in relation to cameras and audio devices, and obtains coordinates of each camera and each audio device. The cameras detects a user. A distance between the user and each audio devices is computed. One audio device is considered as a first audio device. A ratio of audio intensities and a difference of audio transmitting time between the first audio device and each of the other audio devices are computed. Delaying the audio output starting time of each of the other audio devices according to the differences and adjust the audio intensity of each of the other audio devices according to the ratios.

### BACKGROUND

1. Technical Field

Embodiments of the present disclosure relate to devices and methods of audio correction, and more particularly to an electronic device and a method of dynamically correcting audio output of a plurality of audio devices.

2. Description of Related Art

Home cinema, also commonly called home theater, is a home entertainment set-up that seeks to reproduce a movie theater experience and mood with the help of a video and an audio device in a private home. For a user to have the best listening enjoyment, more than one audio device, such as amplifiers, are needed in the home cinema.

However, if the audio devices are not fixed at proper locations in the home cinema, or the user is not sitting at an optimal place, the user still does not have the best listening enjoyment. Thus, two conditions are needed to ensure the audio devices provide an audio output effect with a high quality. That is, the audio devices being fixed at proper locations and the user sitting at the optimal place, must be satisfied simultaneously. In many cases. fixing the locations of the audio devices and the user are difficult.

### BRIEF DESCRIPTION OF THE DRAWINGS

FIG. 1 is a block diagram of one embodiment of an electronic device including an audio output correction system.

FIG. 2 is a block diagram of one embodiment of function modules of the audio output correction system of FIG. 1.

FIG. 3 is a flowchart of one embodiment of a method of dynamically correcting audio output of audio devices.

FIG. 4 is a schematic diagram illustrating a coordinate system in relation to cameras and audio devices.

### DETAILED DESCRIPTION

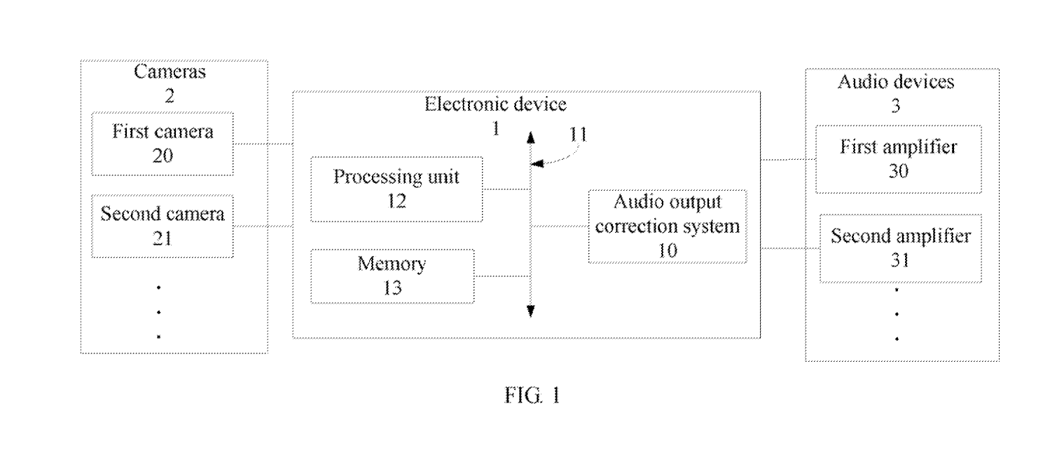

FIG. 1 is a block diagram of one embodiment of an electronic device 1 including an audio output correction system 10. The electronic device 1 may further include components such as, a bus 11, a processing unit 12, and a memory 13. One skilled in the art would recognize that the electronic device 1 may be configured in a number of other ways and may include other or different components. The electronic device 1 may be an audio device, or may be a computer or a server that connects with an audio device.

The electronic device 1 connects with a plurality of cameras 2, such as a first camera 20 and a second camera 21 are shown as examples, and a plurality of audio devices 3, such as a first amplifier 30 and a second amplifier 31 are shown as examples, using a network (not shown). The network may the Internet or an Intranet depending on different embodiments.

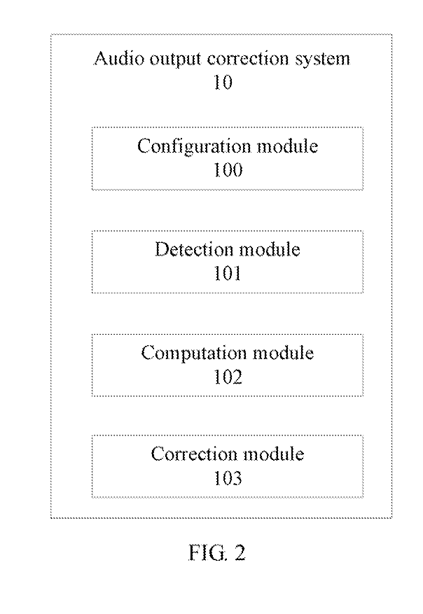

The audio output correction system 10 includes a number of function modules (depicted in FIG. 2). The function modules may include computerized codes in the form of one or more programs, which have functions of dynamically correcting audio output of the devices 3 with the help of the cameras 2, causing the audio output from the audio devices 3 to have the same audio intensity for a user and reach the user at the same time.

The bus 11 of the electronic device 1 permits communications among the components, such as the memory 12 and the processing unit 13 of the electronic device 1.

The processing unit 12 may include a processor, a microprocessor, an application specific integrated circuit (ASIC), and a field programmable gate array (FPGA), for example. The processing unit 12 may execute the computerized codes of the function modules of the audio output correction system 10 to realize the functions of the audio output correction system 10.

The memory 13 may include a random access memory (RAM) or another type of dynamic storage device, a read only memory (ROM) or another type of static storage device, a flash memory, such as an electrically erasable programmable read only memory (EEPROM) device, and/or some other type of computer-readable storage medium, such as a hard disk drive, a compact disc, a digital video disc, or a tape drive. The memory 13 stores the computerized codes of the function modules of the audio output correction system 10 for execution by the processing unit 12

The memory 13 may also be used to store temporary variables/data or other intermediate information, such as, images captured by the cameras 2, and various coordinates of the cameras 2 and the audio device 3, during execution of the computerized codes by the processing unit 12.

Each of the cameras 2 has the face recognition function, and can rotate to capture face images, to detect a user. In other embodiments, the cameras 2 may have no face recognition function, but the electronic device 1 has face recognition software installed, to detect a user using the face images captured by the cameras 2.

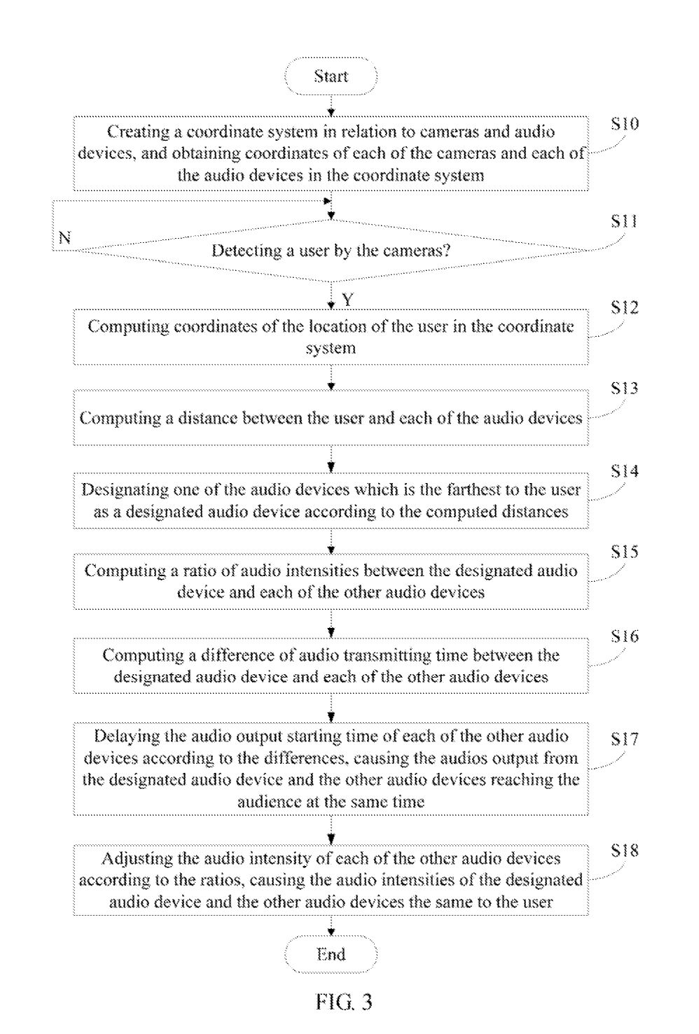

FIG. 2 is a block diagram of one embodiment of the function modules of the audio output correction system 10. In one embodiment, the audio output correction system 10 may include a configuration module 100, a detection module 101, a computation module 102, and a correction module 103. The function modules 100-103 may provide below mentioned functions illustrated in FIG. 3.

FIG. 3 is a flowchart of one embodiment of a method of dynamically correcting audio output of audio devices. Depending on the embodiment, additional steps may be added, others removed, and the ordering of the steps may be changed.

In step S10, the configuration module 100 creates a coordinate system in relation to the cameras 2 and the audio devices 3, and obtains coordinates of each of the cameras 2, such as coordinates of the first camera 20 and the second camera 21, and obtains coordinates of each of the audio devices 3, such as coordinates of the first amplifier 30 and the second amplifier 31, in the coordinate system.

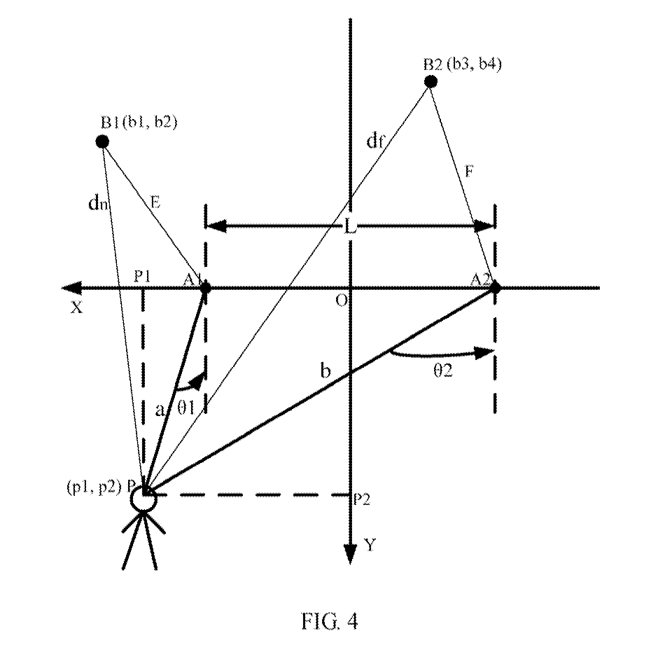

In one embodiment, the configuration module 100 uses a center point of a connecting line of any two of the cameras 2, such as a connecting line of the first camera 20 and the second camera 21, as an origin of the coordinate system, and uses the connecting line of the first camera 20 and the second camera 21 as an X-axis of the coordinate system. The connecting line of two cameras means a line which is formed by connecting two points, each of which represent a location of one of the two cameras. Referring to FIG. 4, A1 represents the first camera 20, and A2 represents the second camera 21, O is the center point of the connecting line of the first camera 20 and the second camera 21. Many variations and modifications may be made to the above-described embodiment to create the coordinate system without departing substantially from the spirit and principles of the disclosure, such as, the configuration module 100 uses a center point of a connecting line of the first amplifier 30 and the second amplifier 31 as the origin of the coordinate system, and uses the connecting line of the first amplifier 30 and the second amplifier 31 as the X-axis of the coordinate system, or uses a center point of a connecting line of the first camera 20 and the first amplifier 30 as the origin of the coordinate system, and uses the connecting line of the first camera 20 and the first amplifier 30 as the X-axis of the coordinate system.

In FIG. 4, B1 represents the first amplifier 30, B2 represents the second amplifier 31. The distances between each two of the audio devices 3, the distances between each two of the cameras 2, and the distances between one of the cameras 2 and one of the audio devices 3, can be measured in the real environment, such as in the home cinema. Thus, in FIG. 4, the distance L between the first camera 20 and the second camera 21, the distance E between the first camera 20 and the first amplifier 20, the distance F between the second camera 21 and the second amplifier 31 are known. In addition, the locations of the cameras 2 and the audio devices 3 are fixed, thus, the coordinates of first camera 20, the second camera 21, the first amplifier 30, and the second amplifier 31 in the coordinate system are known.

In step S11, the detection module 101 determines if a user is detected by the cameras 2. In the present embodiment, when any of the cameras 2 detects a face of a user, this camera 2 rotates a rotation angle to cause the face of a user to be in the center line of the wide angle of this camera 2, then this camera 2 captures an image of the face of a user. If any two of the cameras 2, such as the first camera 20 and the second camera 21, capture images of a face of a user the detection module 101 determines that a user is detected by the cameras 2.

In step S12, the detection module 101 computes coordinates of the location of the user in the coordinate system. In one embodiment, the coordinates are computed according to the rotation angles and the distance of the two cameras 2, such as the first camera 20 and the second camera 21. Referring to FIG. 4, the center lines of the wide angles of the first camera 20 and the second camera 21 are initially vertical to the X-axis of the coordinate system, the first camera 20 rotates a rotation angle θ1 to capture an image of a face of a user, and the second camera 21 rotates a rotation angle θ2 capture an image of the face of a user. The detection module 101 computes coordinates (p1, p2) of the location of the user in the coordinate system using the formulas: (1) a×cos θ1=b×cos θ2, (2) [L+a×sin θ1]²+(a×cos θ1)²=b², (3) p1=L÷2+a×sin θ1, and (4) p2=a×cos θ1. It may be understood that, many variations and modifications may be made to the above-described embodiment to compute coordinates of the location of the user in the coordinate system without departing substantially from the spirit and principles of the disclosure.

In step S13, the computation module 102 computes a distance between the user and each of the audio devices 3. Referring to FIG. 4, the distance do between the user and the first amplifier 30 is computed by dn²=(|b2|+|p2|)²+(|b1|−|p1|)², the distance df between the user and the second amplifier 31 is computed by df²=(|b4|+|p2|)²+(|b3|+p1|)².

In step S14, the computation module 102 designates one of the audio devices 3 as a first audio device 3. In one embodiment, the first audio device 3 is the farthest one from the user according to the above computed distances.

In step S15, the computation module 102 computes a ratio of audio intensities between the first audio device 3 and each of the other audio devices 3. The other audio devices 3 means all the audio devices 3 except the first audio device 3. An audio intensity means an audio volume felt by the user. In one embodiment, the ratio may be computed by the formula: Sₙ=S_{f}×(dₙ÷d_{f})², where Sₙ represents an audio intensity of one of the other audio devices 3, such as the first amplifier 30, S_{f} represents an audio intensity of the first audio device 3, such as the second amplifier 31, dₙ is the distance between the user and the first amplifier 30, and d_{f} is the distance between the user and the second amplifier 31.

In step S16, the computation module 102 further computes a difference of audio transmitting time between the first audio device 3 and each of the other audio devices 3. The audio transmitting time means the total time of an audio signal, which is sent by an audio device, spent on transmitting from the audio device to the user. In one embodiment, the difference may be computed by the formula: Tn=Tf+(df−dn)÷c, where Tn represents the audio transmitting time of one of the other audio devices 3, such as the first amplifier 30, Tf represents the audio transmitting time of the first audio device 3, such as the second amplifier 31, dn is the distance between the user and the first amplifier 30, df is the distance between the user and the second amplifier 31, and c is a sound velocity. The sound velocity in the air at 15° C. is about 340 m/s, and at 28° C. is about 348.5 m/s.

In step S17, the correction module 103 delays the audio output starting time of each of the other audio devices 3 according to the differences, causing the audios output from the first audio device 3 and the other audio devices 3 reaching the user at the same time.

In step S18, the correction module 103 adjusts the audio intensity of each of the other audio devices 3 according to the ratios, causing the first audio device 3 and the other audio devices 3 to output proportional audio intensities to the user.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. A method of dynamically correcting audio output of audio devices, the method being performed by execution of computerized code by a processor of an electronic device and using a plurality of cameras, the method comprising:
(a) creating a coordinate system in relation to the cameras and the audio devices, and obtaining coordinates of each of the cameras and coordinates of each of the audio devices in the coordinate system;
(b) determining if a user is detected by the cameras;
(c) computing coordinates of the location of the user in the coordinate system;
(d) computing a distance between the user and each of the audio devices according to the coordinates of the location of the user and the coordinates of each of the audio devices;
(e) designating one of the audio devices as a first audio device;
(f) computing a ratio of audio intensities between the first audio device and each of the other audio devices;
(g) computing a difference of audio transmitting time between the first audio device and each of the other audio devices;
(h) delaying the audio output starting time of each of the other audio devices according to the differences, causing the audios output from the first audio device and the other audio devices reaching the user at the same time; and
(i) adjusting the audio intensity of each of the other audio devices according to the ratios, causing the first audio device and the other audio devices to output proportional audio intensities to the user.

2. The method according to claim 1, wherein the step (a) comprises:
using a center point of a connecting line of any two of the cameras as the origin of the coordinate system, and using the connecting line of the two cameras as the X-axis of the coordinate system.

3. The method according to claim 1, wherein step (b) comprises:
detecting a user' face using the cameras;
rotating a rotation angle to cause a user' face in the center line of the wide angle of one camera upon condition that the camera detects the user' face;
capturing an image of the user' face by the camera; and
determining that a user is detected upon condition that there are two cameras capturing the images of the user' face.

4. The method according to claim 3, wherein the coordinates of the location of the user are computed according to the rotation angles and the distance of the two cameras that capture the images of the user' face.

5. The method according to claim 1, wherein the ratio is computed using the formula: Sn=Sf×(dn÷df)², wherein Sf represents an audio intensity of the first audio device, Sn represents an audio intensity of one of the other audio devices, dn is the distance between the user and the one of the other audio devices, and df is the distance between the user and the first audio device.

6. The method according to claim 1, wherein the difference is computed using the formula: Tn=Tf+(df−dn)÷c, wherein Tf represents audio transmitting time of the first audio device, Tn represents audio transmitting time of one of the other audio devices, dn is the distance between the user and the one of the other audio devices, df is the distance between the user and the first audio device, and c is a sound velocity.

7. An electronic device, comprising:
a plurality of cameras;
a plurality of audio devices;
a non-transitory storage medium;
at least one processor; and
one or more modules that are stored in the non-transitory storage medium; and are executed by the at least one processor, the one or more modules comprising instructions to:
(a) create a coordinate system in relation to the cameras and the audio devices, and obtain coordinates of each of the cameras and coordinates of each of the audio devices in the coordinate system;
(b) determine if a user is detected by the cameras;
(c) compute coordinates of the location of the user in the coordinate system;
(d) compute a distance between the user and each of the audio devices according to the coordinates of the location of the user and the coordinates of each of the audio devices;
(e) designate one of the audio devices as a first audio device;
(f) compute a ratio of audio intensities between the first audio device and each of the other audio devices;
(g) compute a difference of audio transmitting time between the first audio device and each of the other audio devices;
(h) delay the audio output starting time of each of the other audio devices according to the differences, causing the audios output from the first audio device and the other audio devices reaching the user at the same time; and
(i) adjust the audio intensity of each of the other audio devices according to the ratios, causing the first audio device and the other audio devices to output proportional audio intensities to the user.

8. The electronic device according to claim 7, wherein the plurality of audio devices are amplifiers.

9. The electronic device according to claim 7, wherein the instruction of (a) comprises:
using a center point of a connecting line of any two of the cameras as the origin of the coordinate system, and using the connecting line of the two cameras as the X-axis of the coordinate system.

10. The electronic device according to claim 7, wherein the instruction of (b) comprises:
detecting a user' face using the cameras;
rotating a rotation angle to cause a user' face in the center line of the wide angle of one camera upon condition that the camera detects the user' face;
capturing an image of the user' face by the camera; and
determining that a user is detected upon condition that there are two cameras capturing the images of the user' face.

11. The electronic device according to claim 10, wherein the coordinates of the location of the user are computed according to the rotation angles and the distance of the two cameras that capture the images of the user' face.

12. The electronic device according to claim 7, wherein the ratio is computed using the formula: Sn=Sf×(dn÷df)², wherein Sf represents an audio intensity of the first audio device, Sn represents an audio intensity of one of the other audio devices, dn is the distance between the user and the one of the other audio devices, and df is the distance between the user and the first audio device.

13. The electronic device according to claim 7, wherein the difference is computed using the formula: Tn=Tf+(df−dn)÷c, wherein Tf represents audio transmitting time of the first audio device, Tn represents audio transmitting time of one of the other audio devices, dn is the distance between the user and the one of the other audio devices, df is the distance between the user and the first audio device, and c is a sound velocity.

14. A non-transitory storage medium having stored thereon instructions that, when executed by a processor of an electronic device, causes the processor to:
(a) create a coordinate system in relation to the cameras and the audio devices, and obtain coordinates of each of the cameras and coordinates of each of the audio devices in the coordinate system;
(b) determine if a user is detected by the cameras;
(c) compute coordinates of the location of the user in the coordinate system;
(d) compute a distance between the user and each of the audio devices according to the coordinates of the location of the user and the coordinates of each of the audio devices;
(e) designate one of the audio devices as a first audio device;
(f) compute a ratio of audio intensities between the first audio device and each of the other audio devices;
(g) compute a difference of audio transmitting time between the first audio device and each of the other audio devices;
(h) delay the audio output starting time of each of the other audio devices according to the differences, cause the audios output from the first audio device and the other audio devices reaching the user at the same time; and
(i) adjust the audio intensity of each of the other audio devices according to the ratios, cause the first audio device and the other audio devices to output proportional audio intensities to the user.

15. The non-transitory storage medium according to claim 14, wherein the step (a) comprises:
use a center point of a connecting line of any two of the cameras as the origin of the coordinate system, and use the connecting line of the two cameras as the X-axis of the coordinate system.

16. The non-transitory storage medium according to claim 14, wherein step (b) comprises:
detect a user' face using the cameras;
rotate a rotation angle to cause a user' face in the center line of the wide angle of one camera upon condition that the camera detects the user' face;
capture an image of the user' face by the camera; and
determine that a user is detected upon condition that there are two cameras capturing the images of the user' face.

17. The non-transitory storage medium according to claim 16, wherein the coordinates of the location of the user are computed according to the rotation angles and the distance of the two cameras that capture the images of the user' face.

18. The non-transitory storage medium according to claim 14, wherein the ratio is computed using the formula: Sn=Sf×(dn÷df)², wherein Sf represents an audio intensity of the first audio device, Sn represents an audio intensity of one of the other audio devices, dn is the distance between the user and the one of the other audio devices, and df is the distance between the user and the first audio device.

19. The non-transitory storage medium according to claim 14, wherein the difference is computed using the formula: Tn=Tf+(df−dn)÷c, wherein Tf represents audio transmitting time of the first audio device, Tn represents audio transmitting time of one of the other audio devices, dn is the distance between the user and the one of the other audio devices, df is the distance between the user and the first audio device, and c is a sound velocity.
